(19) United States
(12) Patent Application Publication
(10) Pub. No.: US 2026/0243805 A1
(43) Pub. Date: Aug. 20, 2026

(54) MEASURING HIGH CURRENTS THROUGH A TRANSFORMER

(71) Applicant: SAGEMCOM ENERGY & TELECOM SAS, BOIS-COLOMBES (FR)

(72) Inventors: Christophe GRINCOURT, BOIS-COLOMBES (FR); Christophe FAURE, BOIS-COLOMBES (FR); Henri TEBOULLE, BOIS-COLOMBES (FR)

(21) Appl. No.: 19/545,083

(22) Filed: Feb. 20, 2026

(30) Foreign Application Priority Data
Feb. 20, 2025 (FR) FR2501782

(51) Int. Cl. G01R 15/18; G01R 22/06

(52) U.S. Cl. CPC G01R 15/183; G01R 22/065

(57) ABSTRACT

A current measuring device having a main bar; a secondary bar device having a first end and a second end fixed to the main bar, such that the main current is divided into a first current flowing in the main bar between the first end and the second end of the secondary bar device, and a second current flowing in the secondary bar device; and a current transformer having a magnetic core through which the secondary bar device extends, the current transformer thus making it possible to measure the second current that is representative of the main current.

The invention relates to current measuring devices.

### BACKGROUND

Some electricity meters are designed to measure high currents, such as 200 A or 320 A.

In an electricity meter, the measurement of the current (for a single-phase meter) or of the currents (for a polyphase meter) is conventionally performed using a current measuring transformer for each phase. Indeed, current transformers have a large number of advantages: they are accurate, reliable, robust, and they make it possible to achieve galvanic isolation between the “power” part and the “measurement” sections of the meter.

However, for high currents, and in particular for currents greater than 100 A, the use of current transformers becomes problematic. Indeed, a transformer suitable for such currents has large dimensions. However, the total volume of the meter housing is generally specified by the customer (the energy distributor or the network manager) who purchases the meter from the meter manufacturer. The use of bulky current transformers is therefore very restrictive for the manufacturer of the meter, because it very clearly complicates the integration of the various components inside the meter. The weight of the meter is also increased. In addition, these bulky transformers are expensive, which increases the recurring cost of each meter.

Furthermore, regardless of the current level measured by the meter, current transformers are sensitive to magnetic fields. Some malicious individuals take advantage of this to attempt fraud by placing a SuperMagnet-type magnet near the meter to disrupt the measurements made by the current transformer(s).

### AIM

The aim of the invention is to facilitate the integration of the various components inside an electricity meter, to reduce the weight and cost of the electricity meter, and to reduce its vulnerability to “magnetic” fraud attempts.

### SUMMARY

To achieve this goal, there is provided a current measurement device, arranged to measure a main current flowing in the current measuring device, and comprising:
a main bar;
a secondary bar device comprising a first end and a second end fixed to the main bar, such that the main current is divided into a first current flowing in the main bar between the first end and the second end of the secondary bar device, and a second current flowing in the secondary bar device;
a current transformer, comprising a magnetic core through which the secondary bar device extends, the current transformer thus making it possible to measure the second current that is representative of the main current.

The second current, obtained by dividing the main current and therefore representative of it, has an intensity that may be much lower than that of the main current. For this, it is sufficient that the resistance of the secondary bar device is much greater than that of the portion of the main bar located between the ends of the secondary bar device.

The dimensions of the current transformer, which depend on the current actually measured, may therefore be very significantly reduced.

This facilitates the integration of the various components inside the electricity meter, and reduces the weight and cost of the electricity meter that incorporates one or more current measuring devices.

In addition, since the transformers are smaller, the meter manufacturer has greater freedom in choosing the positioning of the transformers within the housing. This makes it possible to move the transformers away from the internal walls of the housing of the meter. This makes it more difficult to disturb the measurements using a magnet.

In addition, a current measuring device such as described above is proposed, wherein the first end and the second end of the secondary bar device are fixed to the main bar by clinching.

In addition, a current measuring device such as described above is proposed, wherein the first end and the second end of the secondary bar device are fixed to the main bar by hot or cold riveting, or by electric spot welding.

In addition, a current measuring device such as described above is proposed, wherein the secondary bar device comprises a first axial stop and a second axial stop between which the current transformer is positioned and which define an axial position of the current transformer.

In addition, a current measuring device such as described above is proposed, wherein the secondary bar device comprises a first arm, a first end of which is the first end of the secondary bar device, a second arm, a first end of which is the second end of the secondary bar device, and a third arm positioned between a second end of the first arm and a second end of the second arm, the third arm extending through the magnetic core of the current transformer.

In addition, a current measuring device such as described above is provided, wherein a width of the third arm is less than a width of the first arm and a width of the second arm, such that the interface between the third arm and the first arm forms a first shoulder that constitutes the first axial stop and the interface between the third arm and the second arm forms a second shoulder that constitutes the second axial stop.

In addition, a current measuring device such as described above is proposed, wherein the first arm and the second arm both extend from the same side of the main bar, wherein the third arm extends in the continuation of the second arm, and wherein the second arm is folded so that the third arm is offset in height with respect to the first arm to allow a free end of the third arm to be positioned on one side of the first arm.

Also proposed is an item of electrical equipment comprising at least one current measuring device such as described above.

Also proposed is an item of electrical equipment as previously described, the item of electrical equipment being an electricity meter.

The invention shall be better understood in the light of the following description of a specific and non-limiting embodiment of the invention.

### BRIEF DESCRIPTION OF THE DRAWINGS

Reference will be made to the accompanying drawings, among which:

FIG. 1 shows a diagram of a three-phase electricity meter integrating three current measuring devices;

FIG. 2 shows a perspective and top view of the current measuring device;

FIG. 3 shows a perspective and bottom view of the current measuring device;

FIG. 4 shows steps in a configuration method;

### DETAILED DESCRIPTION

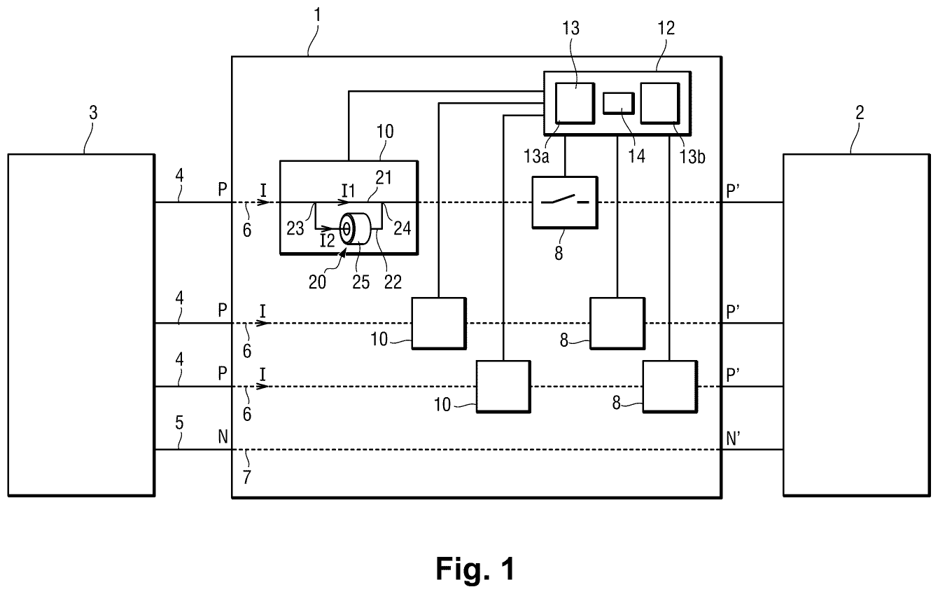

With reference to FIG. 1, the electricity meter 1 is intended to measure the consumption of electrical energy by an installation 2. This electrical energy is supplied to the installation 2 by a distribution network 3. The distribution network 3 comprises three phases 4 and a neutral 5. The meter 1 is a three-phase meter.

The meter 1 comprises, for each phase 4, an upstream phase terminal P connected to said phase 4 and a downstream phase terminal P′ connected to the installation 2. The meter 1 further comprises an upstream neutral terminal N and a downstream neutral terminal N′.

In this example, the term “upstream” means on the side of the distribution network 3, and the term “downstream” means on the side of the installation 2.

The meter 1 further comprises, for each phase 4, a phase conductor 6 connected to the phase 4 of the distribution network 3 via the upstream phase terminal P, and connecting together the upstream phase terminal P and the downstream phase terminal P′.

The meter 1 also comprises a neutral conductor 7 connected to the neutral 5 of the distribution network 3 via the upstream neutral terminal N, and connecting together the upstream neutral terminal N and the downstream neutral terminal N′.

The meter 1 in this case comprises, for each phase 4, a cut-off member 8 comprising a switch connected to the associated phase conductor. The cut-off member 8 is used in particular for remotely interrupting or re-establishing the supply of power to the installation 2, for example in the event of termination of the service subscription or non-compliance with the service contract.

The meter 1 also comprises metrological components.

These metrological components comprise voltage sensors (not shown).

The metrological components also comprise, for each phase 4, a current measuring device 10 which is mounted upstream of the cut-off member 8 on the phase conductor 6. The current measuring device 10 makes it possible to measure the current I flowing on said phase 4 and on said phase conductor 6, which is supplied to the installation 2 by the distribution network 3.

The meter 1 also comprises a processing unit 12 (electronic and software). The processing unit 12 comprises at least one processing component 13, which is for example, a “general-purpose” processor, a processor specialising in signal processing (or DSP, Digital Signal Processor), a microcontroller, or programmable logic circuit, such as an FPGA (Field Programmable Gate Array) or an ASIC (Application-Specific Integrated Circuit). The processing unit 12 also comprises one or more memories 14, connected to or integrated into the processing component 13. At least one of these memories 14 forms a recording medium which can be read by a computer, on which at least one computer program is recorded, comprising instructions which make the processing component 12 execute the steps of the method for measuring current, which will be described below.

In this case, the processing unit 12 comprises a “metrology” microcontroller 13a which belongs to the metrological components and which, in particular, acquires the measurements taken by the sensors of the meter 1 and carries out certain processing operations on said measurements, and an “application” microcontroller 13b which, in particular, controls the cut-off members 8.

Attention is now paid more specifically to current measuring devices 10.

Each current measuring device 10 includes a current measuring transformer 20.

The current measuring transformers 20 are connected to measurement components (not shown), which transform the currents flowing in the secondary of the transformers into measurement voltages. The measurement voltages are digitised by one or more analogue-to-digital converters (not shown), possibly integrated into the metrology microcontroller 13a, and then processed by the metrology microcontroller 13a.

Each current measuring device 10 further comprises a main bar 21 and a secondary bar device 22, which are electrically conductive.

In this case, the term “bar” is used to mean a rigid part, and the term “bar device” is used to mean an assembly of at least one rigid part.

By way of example, the main bar 21 and the secondary bar device 22 are made of copper.

In this example, the main bar 21 comprises a portion (or all) of the phase conductor 6.

The secondary bar device 22 comprises a first end 23 and a second end 24 fixed to the main bar 21, such that the main current I splits into a first current I1 flowing in the main bar 21 between the first end 23 and the second end 24 of the secondary bar device 22, and a second current I2 flowing in the secondary bar device 22.

The current transformer 20 comprises a magnetic core 25 through which the secondary bar device 22 extends, the current measuring transformer 20 thus making it possible to measure the second current I2.

The metrology microcontroller 13a acquires the measurements of the second current I2, and produces measurements of the main current I from said measurements.

The current measuring device 10 thus makes it possible to divide the current so that the second current I2, actually measured, is markedly less than the main current I. This makes it possible to very significantly reduce the size and the weight of the current transformer 10 used. This facilitates the integration of the transformers 20 in the meter 1. The volume available inside the meter 1 is greater, thereby enabling the transformers 20 to be positioned at a distance from the internal walls of the housing of the meter 1 and thus making magnetic fraud more difficult. Furthermore, the small transformers generate a smaller phase shift between the secondary current and the primary current. Therefore, the measurement is more accurate and the in-phase correction is simpler to perform.

An example of an embodiment is provided to illustrate the invention.

In this example, the main current I is equal to 200 A. We assume a temperature of 20° C.

The length of the portion of the main bar 21, between the first end 23 and the second end 24 of the secondary bar device 22, is equal to 20 mm. The main bar 21 has a thickness of 1.8 mm for a width of 25 mm, which gives a cross-sectional area along a plane perpendicular to its length of 45 mm². The impedance of the portion of the main bar 21 which extends between the first end 23 and the second end 24 is 7.7 μΩ.

The length of the secondary bar device 22 is equal to 50 mm. The secondary bar device 22 has a thickness of 0.7 mm for an average width of 5 mm, which gives a cross-sectional area along a plane perpendicular to its length which is equal to 3.5 mm². The impedance of the secondary bar device 22 is equal to 246.3 μΩ.

The first current I1 flowing in the main bar 21 between the first end 23 and the second end 24 of the secondary bar device 22 is equal to 194 A. The second current I2 flowing in the secondary bar device 22 is equal to 6 A.

The current transformer 20 therefore measures a current of 6 A and not 200 A, which makes it possible to very significantly reduce.

The ratio between the diverted current and the total current consumed is proportional to the ratio of the impedances between the secondary bar and the main bar. This ratio is constant regardless of the temperature, as the two bars are made of the same material, in this case copper.

It should be noted that uncertainties that may remain after assembly, such as the length of the secondary bar device 22 and the distance between the two assembly points on the main bar 21, may be compensated for by calibration. This calibration is carried out at the factory.

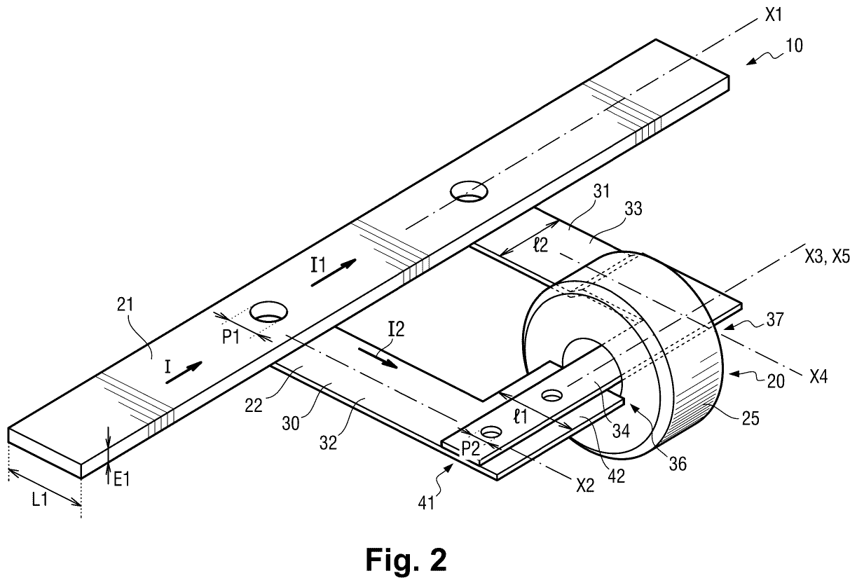

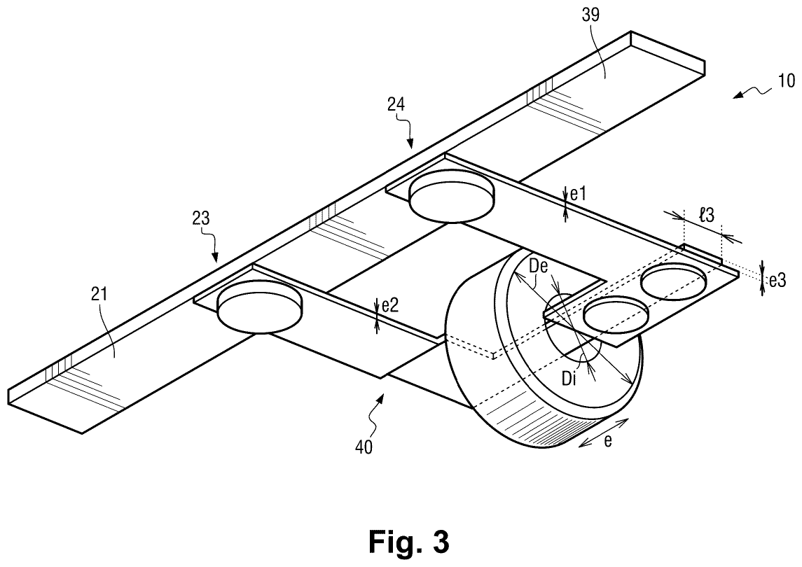

There follows a description of a more precise embodiment of the current measuring device 10 with reference to FIGS. 2 and 3.

In this example, the main bar 21 is in the form of a plate whose length extends along a first axis X1.

In this example, the secondary bar device 22 comprises two parts that are fixed to each other: a first part 30 and a second part 31. These two parts define a first arm 32, a second arm 33, and a third arm 34. The first arm 32 is the first part 30. The second arm 33 and the third arm 34 belong to the second part 31.

The first arm 32 has the shape of an “L” comprising a first branch that extends along a second axis X2 perpendicular to the first axis X1, and a second branch that extends towards the inside of the secondary bar device 22 along a third axis X3 perpendicular to the second axis X2.

The second part 31 has the shape of an “L” comprising a first branch that extends along a fourth axis X4 perpendicular to the first axis X1 (this is the second arm 33), and a second branch that extends towards the inside of the secondary bar device 22 along a fifth axis X5 perpendicular to the fourth axis X4 (this is the third arm 34).

The first end of the first arm 32 is the first end 23 of the secondary bar device 22. The first end of the second arm 33 is the second end 24 of the secondary bar device 22. The third arm 34 is positioned between the second end of the first arm 32 and the second end of the second arm 33.

The core 25 of the current transformer 20 is mounted on the third arm 34. More specifically, the third arm 34 extends through the core 25 of the current transformer 20. The internal diameter Di of the core 25 is very slightly greater than the width l3 of the third arm 34 (typically 1 mm).

The secondary bar device 22 comprises a first axial stop 36 and a second axial stop 37 between which the current transformer 20 is positioned and which define an axial position of the current transformer 20 (along the fifth axis X5).

The width l3 of the third arm 34 is less than the width l1 of the first arm 32 and the width l2 of the second arm 33. The width l3 of the third arm 34 is thus adapted to the small internal diameter Di of the core 25 of the current transformer 20.

This difference in width also has the effect that the interface between the third arm 34 and the first arm 32 forms a first shoulder constituting the first axial stop 36, and the interface between the third arm 34 and the second arm 33 forms a second shoulder constituting the second axial stop 37. The current transformer 20 is therefore positioned and held in place between the first shoulder and the second shoulder.

The thickness e of the core 25 is equal to (or very slightly less than) the distance between the first shoulder and the second shoulder.

The first arm 32 and the second arm 33 both extend from the same face 39 of the main bar 21. Specifically, the face 39 is the lower face of the main bar 21. As has been seen, the third arm 34 extends in the continuation of the second arm 33. The second arm 33 is bent along a bend 40 perpendicular to the axis X 4, such that the third arm 34 is offset in height relative to the first arm 32 to allow the free end 41 of the third arm 34 to be positioned on a face 42 of the first arm 32 (in this case the upper face). The mechanical and geometric configuration of the secondary bar device 22 could be different and, alternatively, the following could be provided:
that the first arm 32 and the second arm 33 are fixed to the upper face and not to the lower face of the main bar 21, and/or
that the third arm 34 is positioned on the lower face of the first arm 32; in this case, the second arm 33 be bent downwards;
that the secondary bar device 22 comprises a different number of arms or parts, or has a different shape;
etc.

Attention is now paid to the fastening of the various parts of the current measuring device 10.

As has been seen, the current transformer 20 is mounted on the third arm 34 and held in place between the first axial stop 36 and the second axial stop 37.

The first end 23 and the second end 24 of the secondary bar device 22 are fixed to the main bar 21 by clinching.

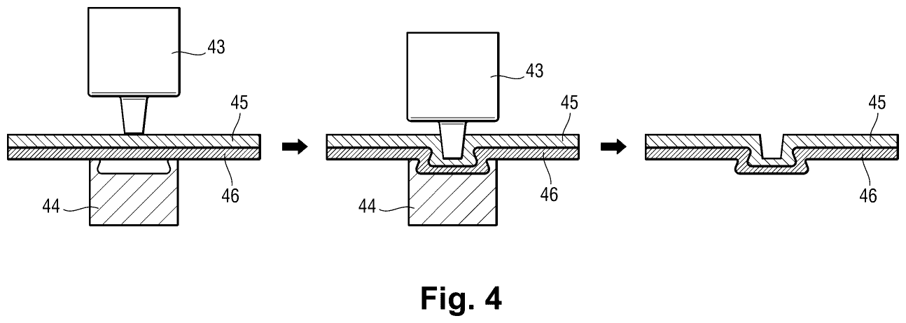

With reference to FIG. 4, clinching requires the use of a punch 43 and a die 44. The clinching makes it possible to fix two metal sheets 45, 46 to each other by stamping. During the clinching process, the metal sheets undergo plastic deformation. The punch 43 is moved with the necessary force depending on the thickness and strength of the materials to be joined, while the die 44 remains fixed.

The advantage of clinching is that it is possible to mix the thicknesses of the two elements to be joined. No preliminary surface treatment is required prior to the operation. No heat input is required. This method has the advantage of not damaging the surface condition of the metals. Surface coatings, such as tin plating on copper or anti-corrosion treatment, are deformed without being damaged. Their characteristics, such as their conductivity, are therefore not degraded.

Clinching does not require welding, which is advantageous because welds can crack when subjected to high temperature variations that they may occur in certain cold countries or during qualification testing.

The relatively large thickness of the main bar 21 requires a punch 43 of a certain diameter to fix the first end 23 and the second end 24 of the secondary bar device 22 to the main bar 21, and therefore this thickness requires that the width l1 of the first arm 32 and the width l2 of the second arm 33 of the secondary bar device 22 be relatively large.

Conversely, since the thickness of the secondary bar device 22 is smaller, the diameter of the punch 43 used to assemble the secondary bar device 22 may be reduced. It is therefore possible to significantly reduce the width l3 of the third arm 34 so that it corresponds to the reduced internal diameter Di of the core 25 of the current transformer 20.

In the embodiment of FIGS. 2 and 3, the main bar 21 has a width L1 of 10 mm and a thickness E1 of 1.8 mm. The first arm 32 and the second arm 33 each have a width l1, l2 of 10 mm and a thickness e1, e2 of 0.7 mm. The third arm 34 has a width l3 of 5 mm and a thickness e3 of 0.7 mm. The outer diameter De of the core 25 of the current transformer 20 is equal to 20 mm. The inner diameter Di of the core 25 is equal to 6 mm. The thickness e of the core 25 is equal to 10 mm.

In this example, the diameter P1 of the punch 43 used to fix the secondary bar device 22 to the main bar 21 is equal to 4 mm.

In this example, the diameter P2 of the punch 43 used to fix the second part 31 to the first part 30 of the secondary bar device 22, and thus the third arm 34 to the first arm 31, is equal to 2.5 mm.

Naturally, the invention is not limited to the embodiments described, but comprises any variant entering into the scope of the invention.

The secondary bar device could be fastened to the main bar in a different way. The first end and the second end of the secondary bar device could for example be fixed to the main bar by hot or cold riveting, or by electric spot welding.

The electricity meter may be a single-phase or polyphase meter comprising a number of phases other than three.

The current device may be integrated in electrical equipment other than an electricity meter, and for example in a circuit breaker.

1. A current measuring device, arranged to measure a main current flowing in the current measuring device, and comprising:
a main bar;
a secondary bar device comprising a first end and a second end fixed to the main bar, such that the main current is divided into a first current flowing in the main bar between the first end and the second end of the secondary bar device, and a second current flowing in the secondary bar device;
a current transformer, comprising a magnetic core through which the secondary bar device extends, the current transformer thus making it possible to measure the second current which is representative of the main current,
the secondary bar device comprising a first axial stop and a second axial stop between which the current transformer is positioned and which define an axial position of the current transformer.

2. The current measuring device according to claim 1, wherein the first end and the second end of the secondary bar device are fixed to the main bar by clinching.

3. The current measuring device according to claim 1, wherein the first end and the second end of the secondary bar device are fixed to the main bar by hot or cold riveting, or by electric spot welding.

4. The current measuring device according to claim 1, wherein the secondary bar device comprises a first arm having a first end that is the first end of the secondary bar device, a second arm having a first end that is the second end of the secondary bar device, and a third arm positioned between a second end of the first arm and a second end of the second arm, the third arm extending through the magnetic core of the current transformer.

5. The current measuring device according to claim 4, wherein a width of the third arm is less than a width of the first arm and a width of the second arm, such that the interface between the third arm and the first arm forms a first shoulder constituting the first axial stop and the interface between the third arm and the second arm forms a second shoulder constituting the second axial stop.

6. The current measuring device according to claim 4, wherein the first arm and the second arm both extend from a same face of the main bar, wherein the third arm extends in the continuation of the second arm, and wherein the second arm is bent so that the third arm is offset in height relative to the first arm to allow a free end of the third arm to be positioned on a face of the first arm.

7. Electrical equipment comprising at least one current measuring device according to claim 1.

8. The electrical equipment according to claim 7, the electrical equipment being an electricity meter.
